(19) United States
(12) Patent Application Publication
(10) Pub. No.: US 2006/0136795 A1
(43) Pub. Date: Jun. 22, 2006

(54) Method of testing scan chain integrity and tester setup for scan block testing

(75) Inventors: Arun Gunda, San Jose, CA (US); Thai Nguyen, San Jose, CA (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/016,412

(22) Filed: Dec. 17, 2004

(51) Int. Cl. G01R 31/28

(52) U.S. Cl. 714/726

(57) ABSTRACT

A method of scan chain integrity testing for an integrated circuit design includes steps of: (a) receiving as input an integrated circuit design; (b) generating a partial shift test bench for the integrated circuit design wherein the partial shift test bench includes scan chains stitched together into shift registers and a scan block; (c) parallel loading the scan chains with a set of test vectors from the scan block with an offset of N bits wherein N is a number greater than one and less than the maximum length of the scan chains; (d) shifting the last N bits of the test vectors into the scan chains with N scan clock pulses; (e) comparing outputs of the scan chains with expected values in the scan block to produce a scan chain integrity test result; and (f) generating as output the scan chain integrity test result.

### BACKGROUND OF THE INVENTION

1. Field of the Invention

The present invention is directed to the testing of integrated circuit devices. More specifically, but without limitation thereto, the present invention is directed to a method of generating tests for integrated circuits that contain clocked elements.

2. Description of Related Art

Modern electronics systems have increased dramatically in circuit density. For example, the densities of integrated circuits have increased from a few hundred transistors per chip in the 1960's to several million transistors per chip in integrated circuits manufactured today. Integrated circuit packaging density has increased from the previous relatively low density dual in-line package (DIP) having a typical pin count of 8 to 40 pins and a pin spacing of 0.1 inch to the current fine-pitch technology (FPT), tape-automated bonding (TAB), and multi-chip modules (MCMs) that provide hundreds of pins in relatively small packages. Conductive trace spacing and trace width on printed circuit boards has also decreased, so that a large number of signals may be routed in a small space. Multi-layer printed circuit boards and single and double-sided surface mount techniques are combined with high levels of integration and high-density integrated circuit packaging techniques to provide extremely dense electronic systems.

As the density of electronic devices increases, device testing becomes increasingly difficult. Traditional test methods include testing circuit board assemblies with testers having a large number of spring-loaded contact pins that make contact with test points on a printed circuit board. Modern fine-pitch technology packages, multi-layer printed circuit boards, and double-sided surface mount techniques frustrate attempts to test high density electronic systems with traditional test methods.

Application specific integrated circuits (ASICs) routinely achieve densities of millions of gates per chip, which presents an especially difficult testing challenge. ASICs are typically designed by combining pre-defined, standard functional blocks called core cells from a variety of sources with discrete logic to perform a desired function or group of functions. Although standard test vectors or test strategies may be supplied with the core cells, their internal connections to one another inside the ASIC are frequently inaccessible from the pins of the ASIC, rendering the standard tests unusable and complicating the testing procedure.

A common technique used to gain access to core cells inside an ASIC is known as full-scan design, in which every flip-flop, or flop, of a logic circuit has a multiplexer placed at its data input, so that when a test mode signal is applied to the control input of the multiplexers, all the flip-flops are chained together into a shift register or scan chain. A scan test is performed by clocking test patterns (stimuli) into the shift register and clocking out the test results (responses).

### SUMMARY OF THE INVENTION

In one aspect of the present invention, a method includes steps of:

(a) receiving as input an integrated circuit design;

(b) generating a partial shift test bench for the integrated circuit design wherein the partial shift test bench includes scan chains stitched together into shift registers and a scan block;

(c) parallel loading the scan chains with a set of test vectors from the scan block with an offset of N bits wherein N is a number greater than one and less than the maximum length of the scan chains;

(d) shifting the test vectors into the last N bits of the scan chains with N scan clock pulses;

(e) comparing outputs of the scan chains with expected values in the scan block to produce a scan chain integrity test result; and

(f) generating as output the scan chain integrity test result.

In another aspect of the present invention, a computer program product for scan chain integrity testing includes a medium for embodying a computer program for input to a computer and a computer program embodied in the medium for causing the computer to perform steps of:

(a) receiving as input an integrated circuit design;

(b) generating a partial shift test bench for the integrated circuit design wherein the partial shift test bench includes scan chains stitched together into shift registers and a scan block;

(c) parallel loading the scan chains with a set of test vectors from the scan block with an offset of N bits wherein N is a number greater than one and less than the maximum length of the scan chains;

(d) shifting the test vectors into the last N bits of the scan chains with N scan clock pulses;

(e) comparing outputs of the scan chains with expected values in the scan block to produce a scan chain integrity test result; and

(f) generating as output the scan chain integrity test result.

### BRIEF DESCRIPTION OF THE DRAWINGS

The present invention is illustrated by way of example and not limitation in the accompanying figures, in which like references indicate similar elements throughout the several views of the drawings, and in which:

FIG. 1 illustrates a typical scan chain of the prior art for an integrated circuit design;

FIG. 2 illustrates a diagram of loading a test vector into a ten-stage scan chain according to the prior art;

FIG. 3 illustrates a diagram of a partial scan shift operation according to an embodiment of the present invention; and

FIG. 4 illustrates a flow chart for a method of performing a scan chain integrity test according to an embodiment of the present invention.

Elements in the figures are illustrated for simplicity and clarity and have not necessarily been drawn to scale. For example, the dimensions of some elements in the figures may be exaggerated relative to other elements to point out distinctive features in the illustrated embodiments of the present invention.

### DESCRIPTION OF THE ILLUSTRATED EMBODIMENTS

In typical scan test methods, a serial and a parallel scan block, that is, a set of scan test vectors, is typically generated for each integrated circuit design. The scan blocks are loaded into a hardware tester used to identify and select defect free integrated circuit chips. The tester reads the scan blocks and applies the test vectors to the inputs of each integrated circuit chip. The outputs of the chip are compared to the expected test results in the scan block. The scan test is repeated for every scan vector in the scan block, and if the scan tests of all the test vectors in the scan blocks are successfully passed, then the next test block is applied. In addition to scan blocks, there are generally other types of test blocks that are used to test an integrated circuit chip before the chip is selected as being defect free. If a failure occurs in a parallel scan block during prototype testing, then the results on the serial scan block are used to analyze the scan test failures. When all scan blocks in the integrated circuit design pass the prototype test, the test program is edited to remove the serial scan block from the design before the design is released for production. The number of test vectors, or scan frames, in a serial scan block typically varies from one to five.

Two significant benefits of serial scan block testing are the validation of scan chain integrity and the validation of the hardware tester setup. Scan chain integrity defines how a scan chain is connected and integrated into a design. If the scan chain is not properly connected, or stitched, then problems may occur when shifting the scan test vector into the scan chain that may cause all scan frames to fail.

Scan shifting is not performed in parallel scan block simulations; instead, the scan cells or flops are loaded and read in series. Serial scan block simulations operate in conjunction with static timing analysis (STA) to assist in identifying incorrect STA setups and to provide a thorough validation of chip functionality, and STA checks path timing.

In serial scan block testing, functional memory is used, that is, memory that is located on the integrated circuit chip. During parallel scan block testing, scan memory in the tester is used to store scan blocks and output data. Serial scan block testing allows the test engineer to classify a detected failure as either a problem with tester setup or an actual design failure. Typically, if the tester setup is incorrect during scan test, the serial scan block simulation will fail, while the serial scan block test will pass.

A disadvantage of serial scan block testing is that increasingly complex designs require longer and longer simulation test times to generate and validate a serial scan block, typically three weeks or more. The long delay in testing has a corresponding impact on the design signoff milestone and the product turnaround time.

In previous methods of testing, the same scan test block is used for both scan chain integrity testing and tester setup validation. However, the scan integrity test determines whether signoff is achieved, that is, all test blocks are validated for the integrated circuit design to confirm that the design netlist is correct and is ready for manufacturing the integrated circuits. On the other hand, the tester setup validation does not affect signoff. If the scan chain integrity test may be performed using a simpler scan test block, then a different design flow may be advantageous even if a longer run time is required to generate the test block for tester setup validation, as this does not affect the design signoff milestone.

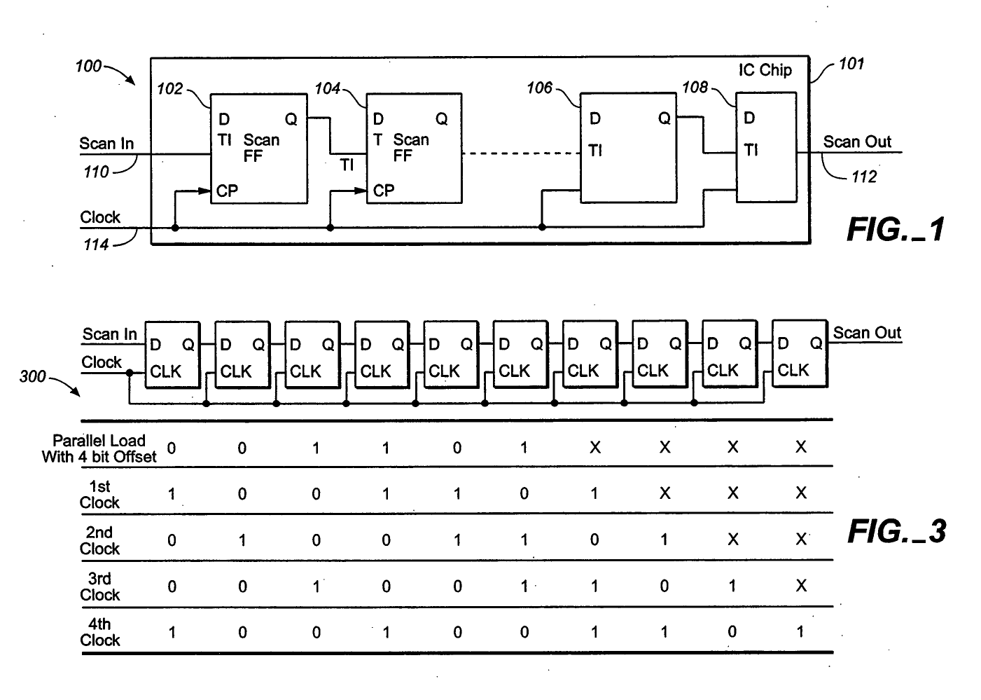

FIG. 1 illustrates a typical scan chain 100 of the prior art for an integrated circuit design. Shown in FIG. 1 are an integrated circuit chip 101, scan flip-flops 102, 104, 106, and 108, a scan shift input port 110, a scan shift output port 112, and a scan clock input port 114.

In the operation of the scan chain 100 illustrated in FIG. 1, test data is loaded into the scan flip-flops 102, 104, 106, and 108 using the scan shift input port 110. The test data is shifted to each of the flip-flops 102, 104, 106, and 108 in turn by applying scan clock pulses to the scan shift input port 110. For every scan clock pulse, test input data is loaded into the test input ports of the flip-flops 102, 104, 106, and 108, and test output data is presented at the Q ports of the flip-flops 102, 104, 106, and 108. If there are N flip-flops in the scan chain, then N scan clock pulses are required to load the entire scan chain with test data.

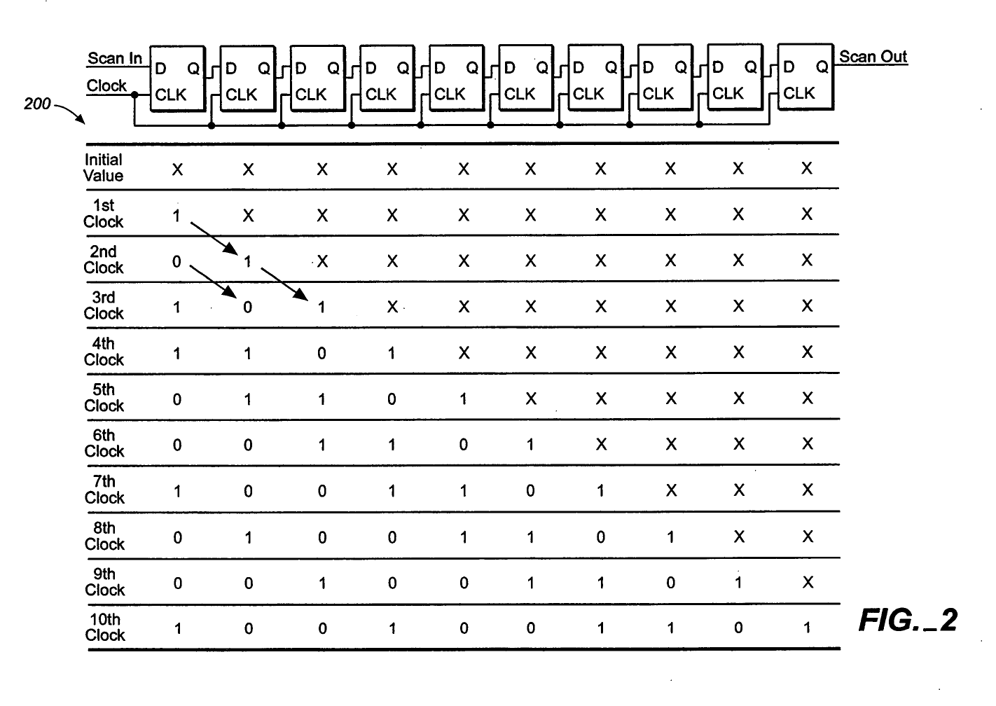

FIG. 2 illustrates a diagram 200 of serially loading a test vector into a ten-stage scan chain according to the prior art. After each scan clock pulse, the test vector, represented by ones and zeroes, replaces the previous data in the next flip-flop in the scan chain, represented by X's. After ten scan clock pulses, the entire test vector “1001001101” is loaded into the scan chain.

In scan chain balancing, the number of clocked elements, for example, flip-flops, is selected so that each scan chain in the integrated circuit design has approximately the same length, for example, within a range of ten percent of the maximum scan chain length. A typical integrated circuit design may have, for example, from four to 32 scan chains. Each scan chain may have a length of several hundred thousand flip-flops. If the length of every scan chain differs significantly, that is, if the scan chains are unbalanced, then the scan memory is not efficiently utilized on the tester. As a result, the number of scan frames or test vectors that may be loaded into the tester is correspondingly reduced. Balancing the scan chains maximizes the number of scan frames that may be loaded into the tester, thereby making most efficient use of the tester memory.

In partial scan chain shift testing, each scan chain is loaded in parallel with an offset of N bits as shown in FIG. 3.

FIG. 3 illustrates a diagram 300 of a partial scan shift operation according to an embodiment of the present invention. In contrast to the full scan shift operation of FIG. 2, all except the last N bits of the scan chain is loaded in parallel with a portion of the test vector. In the example of FIG. 3, N is equal to four. The last N bits are shifted in the same manner as in the example of FIG. 2, and the scan chain outputs are compared to the expected value in the scan block.

Because only N bits are shifted instead of the entire length of the scan chain, the simulation run time is reduced by a factor of the maximum chain length divided by N. For example, if the maximum scan chain length is 6,000 and N is equal to 200, then the simulation run time is reduced by a factor of 6,000/200=30.

A partial shift test bench is created as described above to perform the scan integrity test, for example, using commercially available test software tools such as Mentor. The partial shift test bench is used to perform the scan integrity test, while a full serial scan block test is used as before to perform the tester setup validation. As a result, the simulation run time for the scan integrity test is advantageously reduced.

In one aspect of the present invention, a method of grouping scan flops for scan testing includes steps of:

(a) receiving as input an integrated circuit design;

(b) generating a partial shift test bench for the integrated circuit design wherein the partial shift test bench includes scan chains stitched together into shift registers and a scan block;

(c) parallel loading the scan chains with a set of test vectors from the scan block with an offset of N bits wherein N is a number greater than one and less than the maximum length of the scan chains;

(d) shifting the test vectors into the last N bits of the scan chains with N scan clock pulses;

(e) comparing outputs of the scan chains with expected values in the scan block to produce a scan chain integrity test result; and

(f) generating as output the scan chain integrity test result.

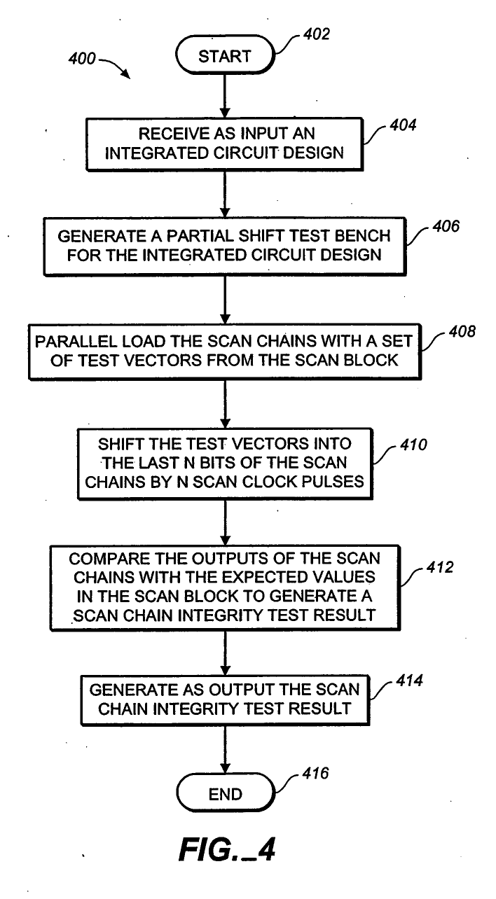

FIG. 4 illustrates a flow chart 400 for a method of performing a scan chain integrity test according to an embodiment of the present invention.

Step 402 is the entry point of the flow chart 400.

In step 404, an integrated circuit design is received as input. The integrated circuit design includes scan chains stitched together into shift registers.

In step 406, a partial shift test bench is generated for the integrated circuit design, for example, on a hardware tester. The partial shift test bench includes scan vectors using the N-bit partial shift method described with reference to FIG. 3. The scan block includes test vectors for loading into the scan chains.

In step 408, the scan vectors are simulated by loading the scan chains in parallel with a set of test vectors from the scan block. The test vectors are loaded into each scan chain with an offset of N bits, where N is a number greater than one to distinguish the partial shift method from the single shift method. N is also significantly less than the maximum length of the scan chains, further distinguishing the partial shift method from the full shift method. N is selected to provide adequate scan chain integrity testing and a desired reduction factor in tester run time.

In step 410, the test vectors are shifted into the last N bits of the scan chains by N scan clock pulses.

In step 412, the outputs of the scan chains are compared with the expected values in the scan block for a scan integrity test by shifting the scan chain N times using N clock cycles. In each clock cycle, the result being shifted out on the scan output port is compared to the corresponding expected value. This allows a comparison of the total N bits from the scan output port. The outputs of all other values from the scan chain elements may be compared in parallel with the expected values. If the outputs of the scan chains all equal the expected values, then the scan chain integrity test result is passed, otherwise, the scan chain integrity test result has failed.

In step 414, the scan chain integrity test result is generated as output. The tester setup validation check may be performed using the full serial scan block test according to well known techniques.

Step 416 is the exit point of the flow chart 200.

The steps described above with regard to the flow chart 400 may also be implemented by instructions performed on a computer according to well-known programming techniques.

In another aspect of the present invention, a computer program product for scan chain integrity testing includes a medium for embodying a computer program for input to a computer and a computer program embodied in the medium for causing the computer to perform steps of:

(a) receiving as input an integrated circuit design;

(b) generating a partial shift test bench for the integrated circuit design wherein the partial shift test bench includes scan chains stitched together into shift registers and a scan block;

(c) parallel loading the scan chains with a set of test vectors from the scan block with an offset of N bits wherein N is a number greater than one and less than the maximum length of the scan chains;

(d) shifting the test vectors into the last N bits of the scan chains with N scan clock pulses;

(e) comparing outputs of the scan chains with expected values in the scan block to produce a scan chain integrity test result; and

(f) generating as output the scan chain integrity test result.

Although the method of the present invention illustrated by the flowchart descriptions above are described and shown with reference to specific steps performed in a specific order, these steps may be combined, sub-divided, or reordered without departing from the scope of the claims. Unless specifically indicated herein, the order and grouping of steps is not a limitation of the present invention.

While the invention herein disclosed has been described by means of specific embodiments and applications thereof, numerous modifications and variations could be made thereto by those skilled in the art without departing from the scope of the invention set forth in the following claims.

What is claimed is:

1. A method comprising steps of:
(a) receiving as input an integrated circuit design that includes scan chains stitched together into shift registers;
(b) generating a partial shift test bench for the integrated circuit design that includes a test vector;
(c) parallel loading the scan chains with the test vector with an offset of N bits wherein N is a number greater than one and less than the maximum length of the scan chains;
(d) shifting the test vector into the last N bits of the scan chains with N scan clock pulses;
(e)
(f) shifting out and reading N scan bits serially from the scan chains;
(g) reading scan bits remaining in the scan chains in parallel;
(h) comparing outputs of the scan chains with expected values to produce a scan chain integrity test; and
(i) generating as output a result of the scan chain integrity test.

2. The method of claim 1 further comprising a step of repeating steps (c), (d), (e), (f), (g), and (h) for each scan frame of a scan block.

3. The method of claim 1 wherein step (b) includes generating the partial shift test bench on a hardware tester.

4. The method of claim 3 further comprising a step of performing a full serial scan test for validating a setup of the hardware tester.

5. The method of claim 1 further comprising a step of balancing the scan chains.

6. A computer program product for scan chain integrity testing comprising:
a medium for embodying a computer program for input to a computer; and
a computer program embodied in the medium for causing the computer to perform steps of:
(a) receiving as input an integrated circuit design;
(b) generating a partial shift test bench for the integrated circuit design wherein the partial shift test bench includes scan chains stitched together into shift registers and a scan block;
(c) parallel loading the scan chains with a set of test vectors from the scan block with an offset of N bits wherein N is a number greater than one and less than the maximum length of the scan chains;
(d) shifting the test vectors into the last N bits of the scan chains with N scan clock pulses;
(e) comparing outputs of the scan chains with expected values in the scan block to produce a scan chain integrity test result; and
(f) generating as output the scan chain integrity test result.

7. The computer program product of claim 6 further comprising a step of repeating steps (c), (d), (e) and (f) for each scan frame in the scan block.

8. The computer program product of claim 6 wherein step (b) includes generating the partial shift test bench on a hardware tester.

9. The computer program product of claim 8 further comprising a step of performing a full serial scan test for validating a setup of the hardware tester.

10. The computer program product of claim 6 further comprising a step of balancing the scan chains.
